(19) United States
(12) Patent Application Publication
(10) Pub. No.: US 2005/0167776 A1
(43) Pub. Date: Aug. 4, 2005

(54) Vertical-type power metal oxide semiconductor device with excess current protective function

(75) Inventor: Takao Arai, Kawasaki-Shi (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI-SHI (JP)

(21) Appl. No.: 11/045,568

(22) Filed: Jan. 31, 2005

(30) Foreign Application Priority Data
Jan. 30, 2004 (JP) 2004-024880

(51) Int. Cl. H01L 27/108

(52) U.S. Cl. 257/500

(57) ABSTRACT

In a vertical-type power metal oxide semiconductor device including a semiconductor substrate, and a plurality of transistor cells formed and arranged on the semiconductor substrate so as to be electrically connected to each other in parallel, the transistor cells are sorted into at least two groups, a first group of transistor cells featuring a gate-threshold voltage which is higher than that of a second group of transistor cells.

### BACKGROUND OF THE INVENTION

1. Field of the Invention

The present invention relates to a vertical-type power metal oxide semiconductor (MOS) device with an excess current protective function.

2. Description of the Related Art

As well known, a vertical-type metal power metal oxide semiconductor (MOS) device is frequently used as a power MOSFET device, because a large amount of drain current can be obtained. In particular, the vertical-type MOSFET device includes a plurality of MOS transistor cells produced and arranged in the semiconductor substrate, and the plurality of transistor cells function as a MOS device. Thus, in the vertical-type MOSFET device, it is possible to obtain a large total amount of drain current.

As also well known, one of the significant factors for evaluating the vertical-type power MOS device is an ON-resistance. Namely, the smaller the ON-resistance, the higher the evaluation of the vertical-type power MOSFET device. In reality, a vertical-type power MOS device featuring a considerably small ON-resistance has been already developed as stated in detail hereinafter.

The vertical-type power MOS device is frequently used as a switch device for controlling driving of an electrical load circuit, such as an electric motor and so on. In this case, the vertical-type power MOS device is associated with a drive/protective circuit which is arranged such that an excess current cannot flow through the vertical-type power MOS device. Otherwise, when a short-circuit occurs in the electrical load circuit, an excess current flows through the vertical-type power MOS device, so that it is thermally damaged.

However, in the vertical-type power MOS device featuring a considerably small ON-resistance, it is very difficult or substantially impossible to properly protect the power MOS device by a drive/protective circuit, for the reasons stated in detail hereinafter.

### SUMMARY OF THE INVENTION

Therefore, an object of the present invention is to provide a vertical-type power metal oxide semiconductor (MOS) device featuring a considerably small ON-resistance, which is constituted so as to be properly protected by a drive/protective circuit.

Another object of the present invention is to provide a combination of such a vertical-type power MOS device and a drive/protective circuit.

In accordance with a first aspect of the present invention, there is provided a vertical-type power metal oxide semiconductor device comprising a semiconductor substrate, and a plurality of transistor cells formed and arranged on the semiconductor substrate so as to be electrically connected to each other in parallel. The transistor cells are sorted into at least two groups, a first group of transistor cells featuring a gate-threshold voltage which is higher than that of a second group of transistor cells.

Preferably, the transistor cells included in the second group are substantially uniformly distributed in the arrangement of all the transistor cells. A percentage of the transistor cells included in the second group may fall within a range between 5% and 20% with respect to a total of the transistor cells. Preferably, all the transistor cells included in the first and second groups are arranged in a matrix manner.

In the first aspect, the transistor cells may be sorted into at least three groups, a first group of transistor cells featuring agate-threshold voltage which is higher than that of a second group of transistor cells, the second group of transistor cells featuring a gate-threshold voltage which is higher than that of a third group of transistor cells. In this case, preferably, the transistor cells included in the second group and the transistor cells included in the third group are substantially uniformly distributed in the arrangement of all the transistor cells. Each of percentages of the transistor cells included in the second group and the transistor cells included in the third group may fall within a range between 5% and 20% with respect to a total of the transistor cells. Preferably, all the transistor cells included in the first, second and third groups are arranged in a matrix manner.

In accordance with a second aspect of the present invention, there is provided a combination of a vertical-type power metal oxide semiconductor device and a drive/protective circuit. The vertical-type power metal oxide semiconductor device comprises a semiconductor substrate, and a plurality of transistor cells formed and arranged on the semiconductor substrate so as to be electrically connected to each other in parallel, and the transistor cells are sorted into at least two groups, a first group of transistor cells featuring a gate-threshold voltage which is higher than that of a second group of transistor cells. The drive/protective circuit is constituted such that a drive voltage is applied to a gate of the vertical-type power metal oxide semiconductor device to thereby turn ON all the transistor cells, and such that a given excess drain current flowing through the vertical-type power metal oxide semiconductor device is detected to thereby turn OFF the transistor cells included in the first group.

In the second aspect, the transistor cells may be sorted into at least three groups, a first group of transistor cells featuring a gate-threshold voltage which is higher than that of a second group of transistor cells, the second group of transistor cells featuring a gate-threshold voltage which is higher than that of a third group of transistor cells. In this case, the drive/protective circuit is constituted such that a drive voltage is applied to a gate of the vertical-type power metal oxide semiconductor device to thereby turn ON all the transistor cells, such that a first given excess drain current flowing through the vertical-type power metal oxide semiconductor device is detected to thereby turn OFF the transistor cells included in the first group, and such that a second given excess drain current, which is larger than the first excess drain current, is detected to thereby turn OFF the transistor cells included in the second group.

### BRIEF DESCRIPTION OF THE DRAWINGS

The above objects and other objects will be more clearly understood from the description set forth below, with reference to the accompanying drawings, wherein:

FIG. 1 is a plan view of a first prior art vertical-type power metal oxide semiconductor (MOS) device;

FIG. 2 is a partial cross-sectional view taken along the lines II-II of FIG. 1;

FIG. 3 is a plan view of a second prior art vertical type MOS device;

FIG. 4 is a partial cross-sectional view taken along the lines IV-IV of FIG. 3;

FIG. 5 is a graph showing a gate-voltage/drain-current characteristic of the first prior art vertical-type power MOS device shown in FIGS. 1 and 2, and a gate-voltage/drain-current characteristic of the second prior art vertical-type power MOS device shown in FIGS. 3 and 4;

FIG. 6 is a wiring diagram of a first type of drive/protective circuit associated with a vertical-type power MOS device;

FIG. 7 is a wiring diagram of a second type of drive/protective circuit associated with a vertical-type power MOS device;

FIG. 8 is a wiring diagram of a third type of drive/protective circuit associated with a vertical-type power MOS device;

FIG. 9 is a wiring diagram of a fourth type of drive/protective circuit associated with a vertical-type power MOS device;

FIG. 10 is a wiring diagram of a fifth type of drive/protective circuit associated with a vertical-type power MOS device;

FIG. 11A is a partial cross-sectional view of an N⁺-type semiconductor substrate and an N⁻-type epitaxial layer formed thereon, showing a first representative step of a production method for manufacturing a first embodiment of a vertical-type power MOS device according to the present invention;

FIG. 11B is a partial cross-sectional view, similar to FIG. 11A, showing a second representative step of the production method for manufacturing the first embodiment of the vertical-type power MOS device according to the present invention;

FIG. 11C is a partial cross-sectional view, similar to FIG. 11B, showing a third representative step of the production method for manufacturing the first embodiment of the vertical-type power MOS device according to the present invention;

FIG. 11D is a partial cross-sectional view, similar to FIG. 11C, showing a fourth representative step of the production method for manufacturing the first embodiment of the vertical-type power MOS device according to the present invention;

FIG. 11E is a partial cross-sectional view, similar to FIG. 11D, showing a fifth representative step of the production method for manufacturing the first embodiment of the vertical-type power MOS device according to the present invention;

FIG. 11F is a partial cross-sectional view, similar to FIG. 11E, showing a sixth representative step of the production method for manufacturing the first embodiment of the vertical-type power MOS device according to the present invention;

FIG. 11G is a partial cross-sectional view, similar to FIG. 11F, showing a seventh representative step of the production method for manufacturing the first embodiment of the vertical-type power MOS device according to the present invention;

FIG. 11H is a partial cross-sectional view, similar to FIG. 11G, showing an eighth representative step of the production method for manufacturing the first embodiment of the vertical-type power MOS device according to the present invention;

FIG. 11I is a partial cross-sectional view, similar to FIG. 11H, showing a ninth representative step of the production method for manufacturing the first embodiment of the vertical-type power MOS device according to the present invention;

FIG. 11J is a partial cross-sectional view, similar to FIG. 11I, showing a tenth representative step of the production method for manufacturing the first embodiment of the vertical-type power MOS device according to the present invention, with this partial cross-sectional view corresponding to one taken along the along J-J of FIG. 12;

FIG. 11K is a partial cross-sectional view, similar to FIG. 11J, showing an eleventh representative step of the production method for manufacturing the first embodiment of the vertical-type power MOS device according to the present invention;

FIG. 12 is a plan view of the first embodiment of the vertical-type power MOS device according to the present invention;

FIG. 13 is a wiring diagram of the first embodiment of the vertical-type power MOS device according to the present invention;

FIG. 14 is a conceptual view showing an arrangement of transistor cells included in the first embodiment of the vertical-type power MOS device according to the present invention;

FIG. 15 is a graph showing a gate-voltage/drain-current characteristic of the first embodiment of the vertical-type power MOS device according to the present invention;

FIG. 16 is a wiring diagram of a drive/protective circuit associated with the first embodiment of the vertical-type power MOS device according to the present invention;

FIG. 17 is a graph showing a drain-voltage/drain-current characteristic of the vertical-type power MOS device associated with the drive/protective circuit shown in FIG. 16;

FIG. 18A is a partial cross-sectional view, similar to FIG. 11F, showing a representative step of a production method for manufacturing a second embodiment of the vertical-type power MOS device according to the present invention;

FIG. 18B is a partial cross-sectional view, similar to FIG. 18A, showing another representative step of the production method for manufacturing the second embodiment of the vertical-type power MOS device according to the present invention;

FIG. 18C is a partial cross-sectional view, similar to FIG. 18B, showing yet another representative step of the production method for manufacturing the second embodiment of the vertical-type power MOS device according to the present invention;

FIG. 18D is a partial cross-sectional view, similar to FIG. 18C, showing still yet another representative step of the production method for manufacturing the second embodiment of the vertical-type power MOS device according to the present invention;

FIG. 19 is a wiring diagram of the second embodiment of the vertical-type power MOS device according to the present invention;

FIG. 20 is a conceptual view showing an arrangement of transistor cells included in the second embodiment of the vertical-type power MOS device according to the present invention;

FIG. 21 is a graph showing a gate-voltage/drain-current characteristic of the second embodiment of the vertical-type power MOS device according to the present invention;

FIG. 22 is a wiring diagram of a drive/protective circuit associated with the second embodiment of the vertical-type power MOS device according to the present invention; and

FIG. 23 is a graph showing a drain-voltage/drain-current characteristic of the vertical-type power MOS device associated with the drive/protective circuit shown in FIG. 22;

### DESCRIPTION OF THE PREFERRED EMBODIMENTS

Before description of an embodiment of the present invention, for better understanding of the present invention, prior art double-diffusion type or vertical-type power metal oxide semiconductor (MOS) devices will be explained with reference to FIGS. 1 to 4.

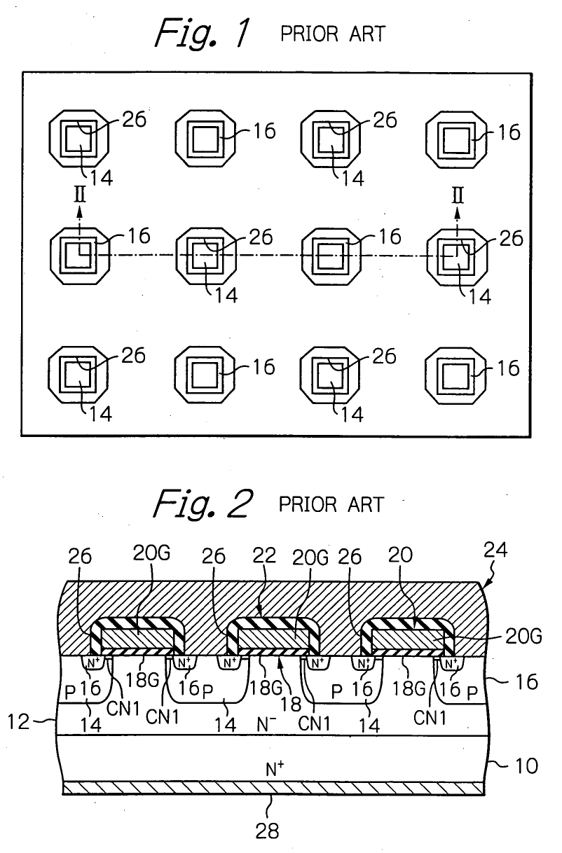

FIGS. 1 and 2 show a structure of a first prior art vertical-type power MOS device.

As shown in FIG. 2, the first prior art vertical-type power MOS device includes an N⁺-type semiconductor substrate 10, which is derived from, for example, an N⁺-type monocrystalline silicon wafer, and an N⁻-type epitaxial layer 12 is formed as a drift layer on the N⁺-type semiconductor substrate 10. A plurality of P-type base regions 14 are formed in the N⁻-type drift layer 12 by implanting P-type impurities, such as boron ions (B⁺) or the like therein, so as to be arranged in a matrix manner over the N⁻-type drift layer 12, and an annular N⁺-type source region 16 is formed in each of the P-type base regions 14 by implanting N-type impurities, such as phosphorus ions (P⁺) or the like therein.

Also, the first prior art vertical-type power MOS device includes a gate insulating layer 18 formed over the N⁻-type drift layer 12, and a gate electrode layer 20 formed over the gate insulating layer 18. The gate insulating layer 18 may be composed of silicon dioxide, and the gate electrode layer 20 may be composed of polycrystalline silicon. The silicon dioxide layer 18 is patterned such that a plurality of gate insulating layer sections 18G are defined so as to bridge a space between two adjacent annular N⁺-type source regions 16, as shown in FIG. 2. Also, the gate electrode layer 20 is patterned in substantially the same configuration as the gate insulating layer 18 to thereby define a plurality of gate electrode layer sections 20G corresponding to the respective gate insulating layer sections 18G.

Further, the first prior art vertical-type power MOS device includes an insulating interlayer 22 formed over the gate electrode layer 20, and a source electrode layer 24 formed over the insulating interlayer 22. The insulating interlayer 22 may be composed of silicon dioxide, and the source electrode layer 24 may be composed of a suitable metal material, such as aluminum or the like. Note, in FIG. 1, the source electrode layer 24 is omitted to illustrate the insulating interlayer 22 in a plan view.

As best shown in FIG. 1, the insulating interlayer 22 is patterned so as to be formed with a plurality of openings 26, and an inner peripheral area of each of the annular N⁺-type source regions 16 and a central area of the P-type base region 14 encompassed by the annular N⁺-type source region 16 concerned are exposed to the outside. The formation of the source electrode layer 24 is carried out such that the openings 26 are filled with the metal material forming the source electrode layer 24, and thus the source electrode layer 24 is in electrical contact with each of the annular N⁺-type source regions 16. As shown in FIG. 2, a drain electrode layer 28 is formed on the rear surface of the N⁺-type semiconductor substrate 10. Note, in this vertical-type power MOS device, both the N⁺-type semiconductor substrate 10 and the N⁻-type drift layer 12 function as a drain region.

Thus, in the vertical-type power MOS device as shown in FIG. 2, when the gate-source is forwardly biased, a horizontal inversion region or channel CN1 is produced at the annular surface area of each of the P-type base regions 14, which is sited beneath the gate electrode layer section 20G, and which surrounds a corresponding annular N⁺-type source region 16, whereby an ON-current flows from the annular N⁺-type source regions 16 toward the drain electrode layer 28 through both the N⁻-type drift layer 12 and the N⁺-type semiconductor substrate 10 in accordance with a voltage applied between the annular N⁺-type source regions 16 and the drain electrode layer 28.

As well known, an amount of the ON-current depends upon an ON-resistance produced in the interior of the power MOS device. In general, the ON-resistance is defined as a sum of resistance values of the N⁺-type source region 16, the horizontal annular channels CN1, the N⁻-type drift layer 12 and the N⁺-type semiconductor substrate 10. However, in the vertical-type power MOS device as shown in FIGS. 1 and 2, the ON-resistance further includes a junction FET resistance produced between the two adjacent P-type base regions 14. In particular, while the gate-source is forwardly biased, a depletion region is created along the P-N junction between each of the P-type base regions 14 and the N⁻-type drift layer 12 such that the ON-current flowing through the N⁻-type drift layer 12 is restricted. In short, in the vertical-type power MOS device shown in FIGS. 1 and 2, the junction FET resistance is relatively large, and thus the ON-resistance becomes larger.

As is apparent from the forgoing, the vertical-type power MOS device includes a plurality of MOS transistors arranged in a matrix manner in the N⁺-type semiconductor substrate 10, and each of the MOS transistors is referred to as a transistor cell. Namely, the plurality of transistor cells function as a MOS device. Thus, in the vertical-type power MOS device, it is possible to obtain a large total amount of drain current. Note, in the example shown in FIGS. 1 and 2, although the vertical-type power MOS device includes only the twelve transistor cells, in reality, there are more than several thousand of the transistor cells therein.

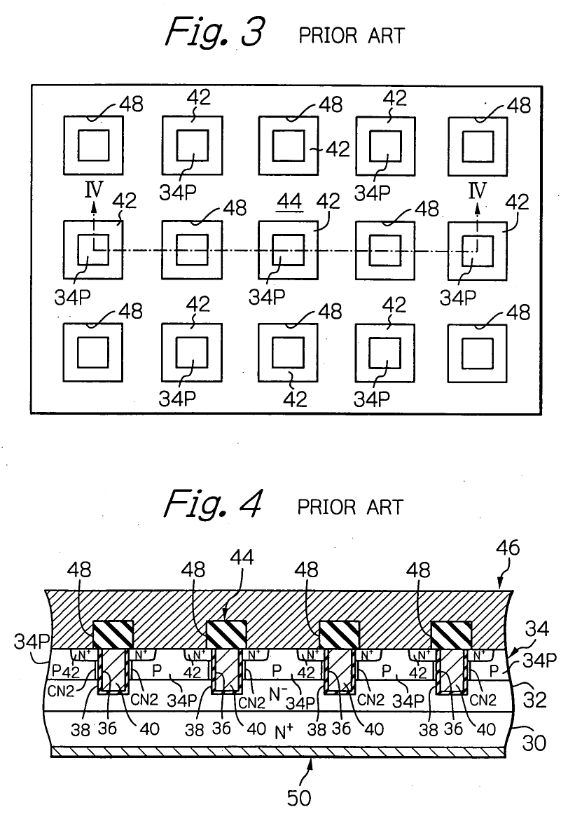

FIGS. 3 and 4 show a structure of a second prior art vertical-type power MOS device which is directed to an improvement of the first prior art vertical-type power MOS device. In the second prior art vertical-type power MOS device, it is possible to considerably lower the ON-resistance, as discussed below.

As shown in FIG. 3, the second prior art vertical-type power MOS device also includes an N⁺-type semiconductor substrate 30, which is derived from, for example, an N⁺-type monocrystalline silicon wafer, and an N⁻-type epitaxial layer 32 is formed as a drift layer on the N⁺-type semiconductor substrate 30. A P-type layer 34 is formed in the N⁻-type epitaxial or N⁻-type drift layer 32 by implanting P-type impurities, such as boron ions (B⁺) or the like therein, Namely, the surface of portion of the N⁻-type drift layer 32 is reformed as the P-type layer 34 due to the implantation of the P-type impurities therein. Then, a lattice-like trench 36 is formed in both the P-type layer 34 and the N⁻-type drift layer 32 such that the P-type layer 34 is sectioned into a plurality of P-type base regions 34P. Namely, the p-type base regions 34P are arranged in a matrix manner over the N⁻-type drift layer 32.

After the formation of the lattice-like trench 36, an inner wall face of the lattice-like trench 36 is reformed as a silicon dioxide layer or gate insulating layer 38 by using a thermal oxidization process. Then, the lattice-like trench 36 is filled with polycrystalline silicon, to thereby produce a gate electrode layer 40. Subsequently, an annular N⁺-type source region 42 is formed in each of the P-type base regions 34P by implanting N-type impurities, such as phosphorus ions (P⁺) or the like therein, so that an outer periphery of the annular N⁺-type source region 42 is in contact with the lattice-like gate insulating layer 38.

Also, the second prior art vertical-type power MOS device includes an insulating interlayer 44 formed over the P-type layer 34, and a source electrode layer 46 formed over the insulating interlayer 44. The insulating interlayer 44 may be composed of silicon dioxide, and the source electrode layer 46 may be composed of a suitable metal material, such as aluminum or the like. Note, in FIG. 3, the source electrode layer 46 is omitted to illustrate the insulating interlayer 44 in a plan view.

As best shown in FIG. 3, the insulating interlayer 44 is patterned so as to be formed with a plurality of openings 48, and an inner peripheral area of each of the annular N⁺-type source regions 42 and a central area of the P-type base region 34P encompassed by the annular N⁺-type source region 42 concerned are exposed to the outside. The formation of the source electrode layer 46 is carried out such that the openings 48 are filled with the metal material forming the source electrode layer 46, and thus the source electrode layer 46 is in electrical contact with each of the annular N⁺-type source regions 34P. As shown in FIG. 4, a drain electrode layer 50 is formed on the rear surface of the N⁺-type semiconductor substrate 30. Note, similar to the first prior art vertical-type power MOS device, both the N⁺-type semiconductor substrate 30 and the N⁻-type drift layer 32 function as a drain region.

Thus, in the second prior art vertical-type power MOS device as shown in FIG. 4, when the gate-source is forwardly biased, a vertical inversion region or channel CN2 is produced at the peripheral side area of each of the P-type base regions 14, which is in contact with the gate electrode layer 38, whereby an ON-current flows from the annular N⁺-type source regions 42 toward the drain electrode layer 50 through both the N⁻-type drift layer 32 and the N⁺-type semiconductor substrate 30 in accordance with a voltage applied between the annular N⁺-type source regions 42 and the drain electrode layer 50.

In the second prior art vertical-type power MOS device as shown in FIGS. 3 and 4, while the gate-source is forwardly biased, a depletion region is created along the P-N junction between each of the P-type base regions 34P and the N⁻-type drift layer 32, but the creation of the depletion region is not performed so as to restrict the ON-current flowing through the N⁻-type drift layer 12. Thus, the ON-resistance is smaller in comparison with that of the aforesaid vertical-type power MOS device shown in FIGS. 1 and 2.

Note, in the example shown in FIGS. 3 and 4, although the vertical-type power MOS device includes only the fifteen transistor cells, in reality, there are more than several thousand of the transistor cells therein, similar to the aforesaid first prior art vertical-type power MOS device.

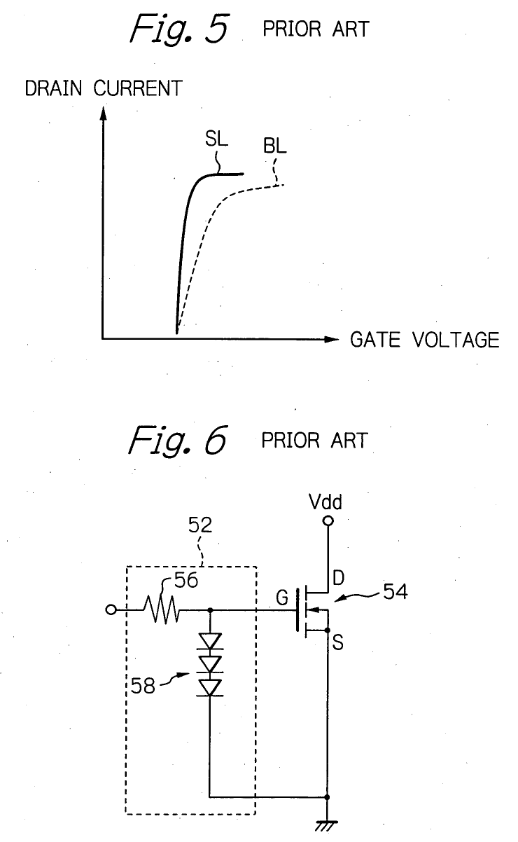

In a graph shown in FIG. 5, a gate-voltage/drain-current characteristic of the first prior art vertical-type power MOS device (FIGS. 1 and 2) is represented by a broken curve BL, and a gate-voltage/drain-current characteristic of the second prior art vertical-type power MOS device (FIGS. 3 and 4) is represented by a solid curve SL. Note, in this graph, the abscissa representing a gate voltage applied to each of the gates of the first and second prior art power MOS devices is defined as a linear scale, whereas the ordinate representing a drain-current flowing through each of the drains of the first and second prior art power MOS devices is defined as a logarithmic scale.

As is apparent from the graph of FIG. 5, the characteristic SL is especially and considerably steeper in comparison with the characteristic BL, because the ON-resistance of the second prior art vertical-type power MOS device is smaller than that of the first prior art vertical-type power MOS device, as stated above.

By the way, each of the above-mentioned prior art vertical-type power MOS devices is frequently used as a switch device for controlling driving of an electrical load circuit, such as an electric motor and so on. In this case, the vertical-type power MOS device is associated with a drive/protective circuit which is arranged such that an excess current cannot flow through the vertical-type power MOS device. Otherwise, when a short-circuit occurs in the electrical load circuit, an excess current flows through the vertical-type power MOS device, so that it is thermally damaged.

In general, five representative types of drive/protective circuits for protecting the vertical-type power MOS device from the excess current flowing therethrough are known.

With reference to FIG. 6, a first type of drive/protective circuit is generally indicated by reference 52, and is associated with a vertical-type power MOS device 54, which may be the aforesaid first prior art power MOS device FIGS. 1 and 2). A drain D of the power MOS device 54 is connected to a main power source (not shown) through the intermediary of an electrical load circuit (not shown), and a source S of the power MOS device 54 is grounded. The power MOS device 54 serves as a switch device for controlling driving of the electrical load circuit, and a drain voltage V_{dd} is applied to the drain D of the power MOS device 54 from the main power source through the intermediary of the electrical load circuit.

The drive/protective circuit 52 includes a resistor 56, one terminal of which is connected to a gate G of the power MOS device 54, and the other terminal of the resistor 56 is connected to a power source (not shown) The drive/protective circuit 52 further includes a set of diodes 58 arranged as shown in FIG. 6. Thus, a low voltage, which is determined by the set of diodes 58, is always applied to the gate G of the power MOS device 54, whereby the power MOS device 54 is protected by restraining a current flowing therethrough.

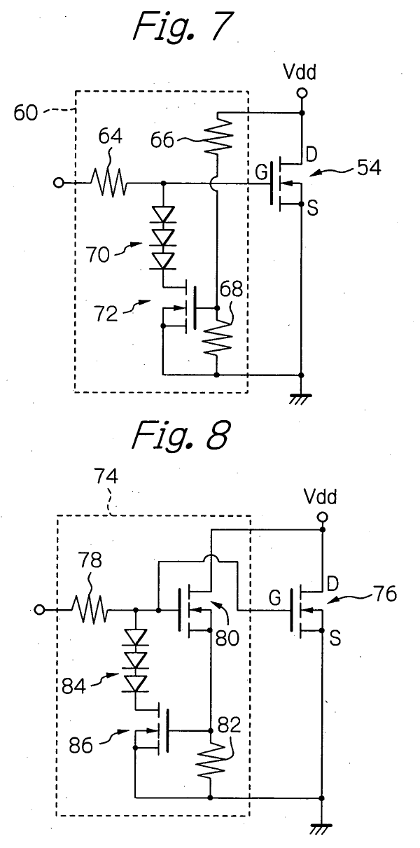

With reference to FIG. 7, a second type of drive/protective circuit is generally indicated by reference 60, and is associated with a vertical-type power MOS device 62, which may be the aforesaid first prior art power MOS device FIGS. 1 and 2). Similar to the aforesaid power MOS device 54, a drain D of the power MOS device 62 is connected to a main power source (not shown) through the intermediary of an electrical load circuit (not shown), and a source S of the power MOS device 62 is grounded. The power MOS device 62 serves as a switch device for controlling driving of the electrical load circuit, and a drain voltage V_{dd} is applied to the drain D of the power MOS device 62 from the main power source through the intermediary of the electrical load circuit.

The drive/protective circuit 60 includes a resistor 64, one terminal of which is connected to a gate G of the power MOS device 62, and the other terminal of the resistor 64 is connected to a power source (not shown). The drive/protective circuit 60 further includes two resistors 66 and 68, a set of diodes 70, and a MOS transistor 72, which are arranged as shown in FIG. 7. With this arrangement, the MOS transistor 72 is turned ON when a drain voltage applied to the drain D of the power MOS device 62 exceeds a predetermined value due to, for example, a short-circuit occurring in the electrical load circuit, i.e. when an excess current flows through the power MOS device 62, whereby a gate voltage applied to the gate G of the power MOS device 62 is decreased to a low voltage determined by the set of diodes 70. Thus, it is possible to protect the power MOS device 62 from the excess current flowing therethrough during the occurrence of the short-circuit in the electrical load circuit.

With reference to FIG. 8, a third type of drive/protective circuit is generally indicated by reference 74, and is associated with a vertical-type power MOS device 76, which may be the aforesaid first prior art power MOS device FIGS. 1 and 2). Similar to the aforesaid power MOS devices 54 and 62, a drain D of the power MOS device 74 is connected to a main power source (not shown) through the intermediary of an electrical load circuit (not shown), and a source S of the power MOS device 74 is grounded. The power MOS device 74 serves as a switch device for controlling driving of the electrical load circuit, and a drain voltage V_{dd} is applied to the drain D of the power MOS device 74 from the main power source through the intermediary of the electrical load circuit.

The drive/protective circuit 74 includes a resistor 78, one terminal of which is connected to a gate G of the power MOS device 76, and the other terminal of the resistor 78 is connected to a power source (not shown). The drive/protective circuit 74 further includes a MOS transistor 80, a resistor 82, a set of diodes 84, and a MOS transistor 86, which are arranged as shown in FIG. 8. In this arrangement, each of the MOS transistors 80 and 86 is usually maintained at an OFF state, but these MOS transistors 80 and 86 are turned ON in order when a drain current flowing through the power MOS device 76 exceeds a predetermined value due to, for example, a short-circuit occurring in the electrical load circuit, whereby a gate voltage applied to the gate G of the power MOS device 76 is lowered to a low voltage determined by the set of diodes 84. Thus, it is possible to protect the power MOS device 76 from the excess current flowing therethrough during the occurrence of the short-circuit in the electrical load circuit.

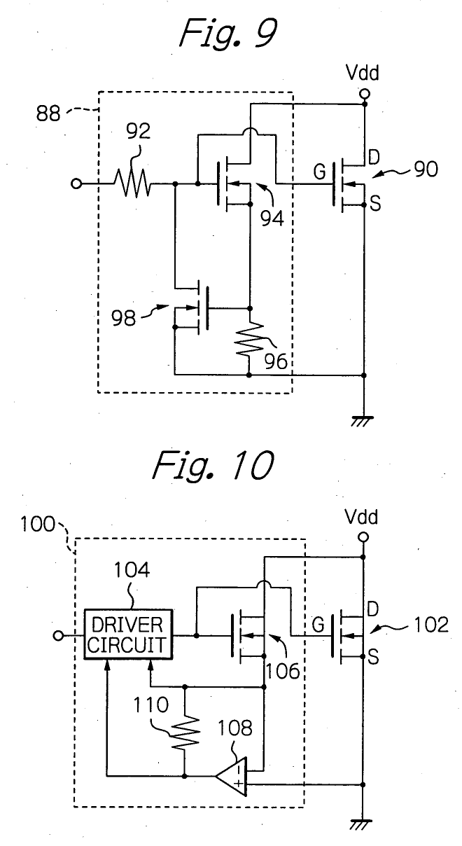

With reference to FIG. 9, a fourth type of drive/protective circuit is generally indicated by reference 88, and is associated with a vertical-type power MOS device 90, which may be the aforesaid first prior art power MOS device FIGS. 1 and 2). Similar to the aforesaid power MOS devices 54, 62 and 76, a drain D of the power MOS device 90 is connected to a main power source (not shown) through the intermediary of an electrical load circuit (not shown), and a source S of the power MOS device 90 is grounded. The power MOS device 90 serves as a switch device for controlling driving of the electrical load circuit, and a drain voltage V_{dd} is applied to the drain D of the power MOS device 90 from the main power source through the intermediary of the electrical load circuit.

The drive/protective circuit 88 includes a resistor 92, one terminal of which is connected to a gate G of the power MOS device 90, and the other terminal of the resistor 92 is connected to a power source (not shown). The drive/protective circuit 88 further includes a MOS transistor 94, a resistor 96, and a MOS transistor 98, which are arranged as shown in FIG. 9. In this arrangement, each of the MOS transistors 94 and 98 is usually maintained at an OFF state, but these MOS transistors 94 and 98 are turned ON in order when a drain current flowing through the power MOS device 90 exceeds a predetermined value, whereby a gate voltage applied to the gate G of the power MOS device 90 is lowered and focused to a given target value in accordance with an amount of the drain current flowing through the power MOS device 90. Namely, the larger the amount of the drain current flowing through the power MOS device 90, the smaller the gate voltage applied to the gate G of the power MOS device 76, and vice versa. Thus, it is possible to protect the power MOS device 90 from an excess current flowing therethrough when a short-circuit occurs in the electrical load circuit.

With reference to FIG. 10, a fifth type of drive/protective circuit is generally indicated by reference 100, and is associated with a vertical-type power MOS device 102, which may be the aforesaid first prior art power MOS device FIGS. 1 and 2. Similar to the aforesaid power MOS devices 54, 62, 76 ad 90, a drain D of the power MOS device 102 is connected to a main power source (not shown) through the intermediary of an electrical load circuit (not shown), and a source S of the power MOS device 102 is grounded. The power MOS device 102 serves as a switch device for controlling driving of the electrical load circuit, and a drain voltage V_{dd} is applied to the drain D of the power MOS device 102 from the main power source through the intermediary of the electrical load circuit.

The drive/protective circuit 100 includes a driver circuit 104 for driving the power MOS device 102, and the driver circuit 104 has an input terminal connected to a power source (not shown), and an output terminal connected to a gate G of the power MOS device 100. The drive/protective circuit 100 further includes a MOS transistor 106, an operational amplifier 108, and a resistor 110, which are arranged as shown in FIG. 10. In this arrangement, the MOS transistors 106 is usually maintained at an OFF state, but this MOS transistor 106 is turned ON when a drain current flowing through the power MOS device 102 exceeds a predetermined value. After the MOS transistor 106 is turned ON, the driver circuit 104 detects whether an amount of a drain current flowing through the MOS transistor 106 is increased or decreased through the operational amplifier 108 and the resistor 110. If the drain current flowing through the MOS transistor 106 is increased, a gate voltage applied from the driver circuit 104 to the gate G of the power MOS device 102 is lowered and focused to a given target value in accordance with the increase of the drain current flowing through the MOS transistor 106. If the drain current flowing through the MOS transistor 106 is decreased, the gate voltage applied from the driver circuit 104 to the gate G of the power MOS device 102 is raised in accordance with the decrease of the drain current flowing through the MOS transistor 106. Thus, it is possible to protect the power MOS device 102 from an excess current flowing therethrough when a short-circuit occurs in the electrical load circuit.

Note that a concept of the third type of drive/protective circuit shown in FIG. 8 is disclosed in JP-A-H09-139633. Also, note that a concept of the fourth and fifth types of drive/protective circuit shown in FIGS. 9 and 10 is disclosed in, for example, JP-A-2003-232816.

In the prior art examples shown in FIGS. 6 to 10, each of the drive/protective circuits 52, 60, 74, 88 and 100 may be produced in a margin area of the semiconductor substrate in which a corresponding vertical-type power MOS device (54, 62, 76, 90, 102) is provided. Otherwise, each of the drive/protective circuits 52, 60, 74, 88 and 100 may be produced in an independent semiconductor substrate. In this case, the drive/protective circuit concerned is mounted together with a corresponding vertical-type power MOS device (54, 62, 76, 90, 102) on a wiring board such that electrical connections are established therebetween.

As is apparent from the foregoing, by using each of the drive/protective circuits 52, 60, 74, 88 and 100, it is possible to protect the first prior art vertical-type power MOS device (FIGS. 1 and 2). Nevertheless, it is very difficult or substantially impossible to properly protect the second prior art vertical-type power MOS device (FIGS. 3 and 4) by each of the drive/protective circuits 52, 60, 74, 88 and 100, due to the steep gate-voltage/drain-current characteristic SL (FIG. 5) of the second prior art vertical-type power MOS device.

In particular, for example, when a plurality of second prior art vertical-type power MOS devices (FIGS. 3 and 4) are produced together with drive/protective circuits in a silicon wafer by using various well-known processes, the elements forming each of the power MOS devices and the elements forming each of the drive/protective circuits are subjected to process fluctuations. As a result, for example, gate-threshold voltages of the transistor cells included in each of the power MOS devices may fluctuate. Similarly, for example, resistance values of the resistors included in the respective drive/protective circuits may fluctuate. These fluctuations exert a large influence on a gate voltage to be applied to the gate of the power MOS device, so that the gate voltage also fluctuates in the individual power MOS devices.

In the second prior art vertical-type power MOS device (FIGS. 3 and 4), the fluctuation of the gate voltage cannot be ignored due to the steep gate-voltage/drain-current characteristic SL (FIG. 5). Namely, although the fluctuation of the gate voltage is very small, it causes a considerably large change in a drain current flowing through the power MOS device, and thus it is substantially impossible to properly control the gate voltage to applied to the gate of the power MOS device. For example, in the drive/protective circuits (60 and 74) as shown in FIGS. 7 and 8, if the gate voltage is set to be slightly high, a large amount of drain current could flow through the power MOS device, resulting in thermal damage thereof. Also, in the drive/protective circuits (88 and 100) as shown in FIGS. 9 and 10, there may be a case where it is impossible to lower and focus the gate voltage to a given target value in accordance with an increase of the drain current flowing through the power MOS device due to the steep gate-voltage/drain-current characteristic SL, so that an oscillation is generated in the drive/protective circuit (88, 100).

In short, it is substantially impossible to properly protect the second prior art vertical-type power MOS device (FIGS. 3 and 4) by each of the drive/protective circuits 52, 52, 60, 74, 88 and 100, due to the steep gate-voltage/drain-current characteristic SL thereof.

### First Embodiment

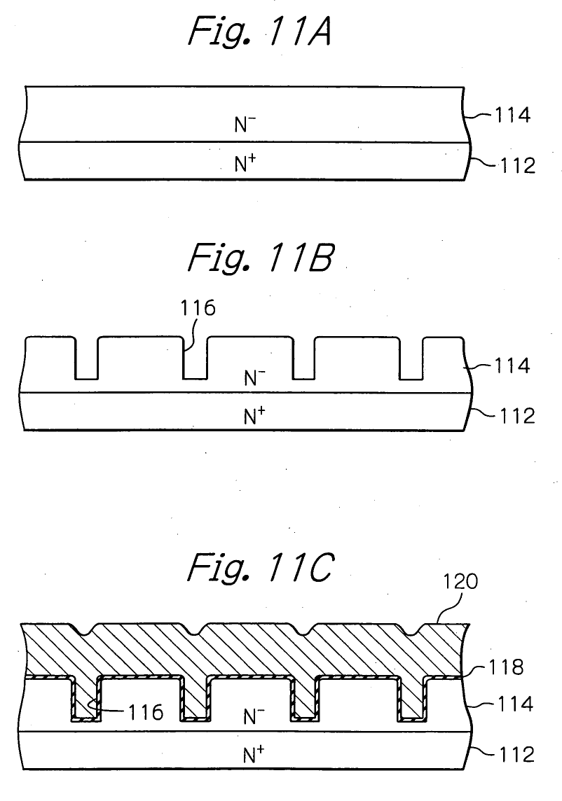

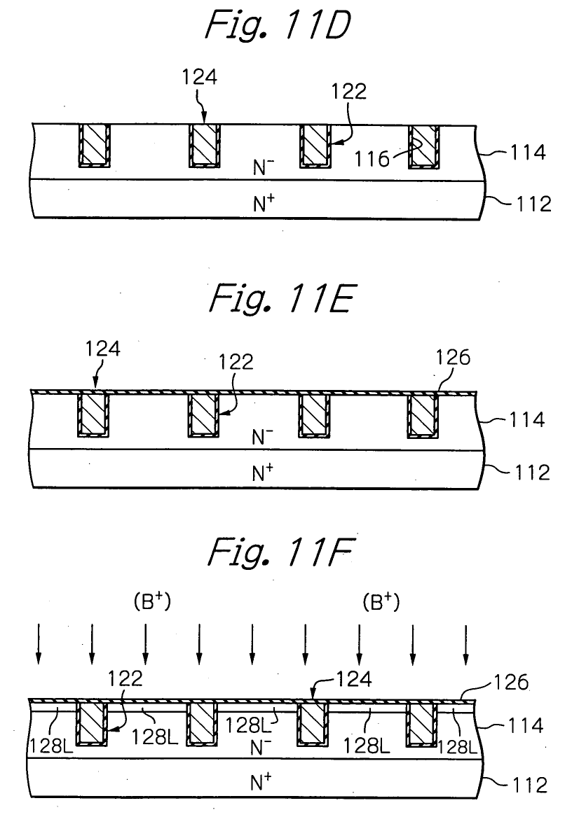

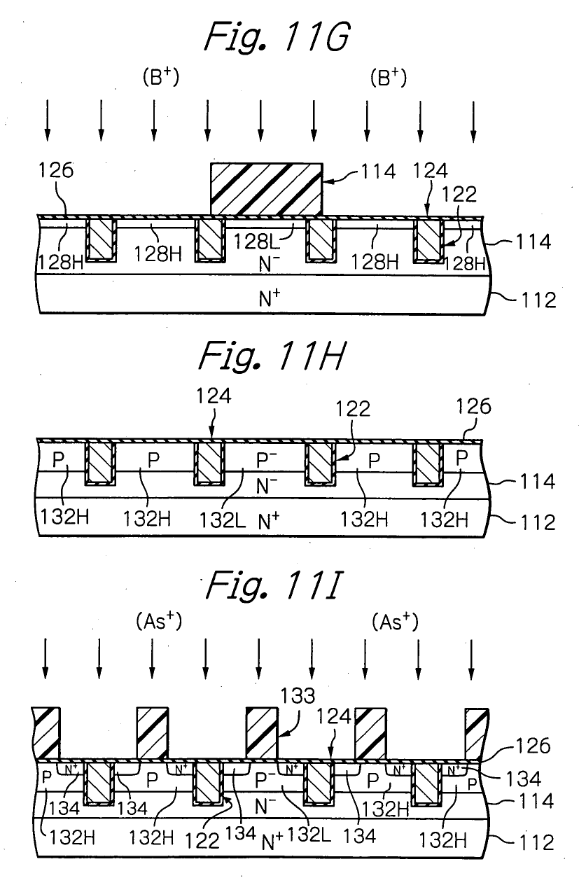

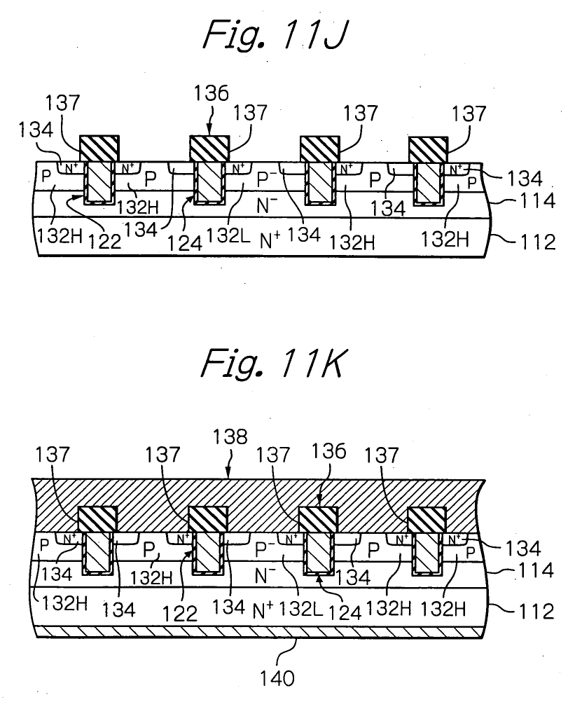

With reference to FIGS. 11A to 11J, a production method for manufacturing a first embodiment of a vertical-type power MOS device according to the present invention will now be explained.

First, as shown in FIG. 11A, an N⁺-type semiconductor substrate 112 is prepared, and an N⁻-type epitaxial layer 114 is formed as an N⁻-type drift layer on the N⁺-type semiconductor substrate 112. The N⁺-type semiconductor substrate 122 is derived from, for example, an N⁺-type monocrystalline silicon wafer in which N-type impurities, such as arsenic (As⁺) or the like, and a plurality of chip areas, in which vertical-type power MOS devices are to be produced, are defined on the N⁺-type semiconductor substrate 122 by scribe lines. Also, the N⁻-type epitaxial or drift layer 114 contains N-type impurities, such as arsenic (As⁺) or the like.

After the formation of the N⁻-type drift layer 114 is completed, as shown in FIG. 11B, a lattice-like trench 116 is formed in the N⁻-type drift layer 114 by using a photolithography process and a wet or dry etching process. Then, the N⁻-type drift layer 114 having the lattice-like trench 116 is subjected to a thermal oxidization process, such that a silicon dioxide layer 118 is formed on the N⁻-type drift layer 114, as shown in FIG. 1C. Namely, a top surface of the N⁻-type drift layer 114 and an inner wall face of the lattice-like trench 116 is reformed by the thermal oxidization process so as to be covered with the silicon dioxide layer 118. Subsequently, as shown FIG. 11C, a polycrystalline silicon layer 120 is formed on the silicon dioxide layer 118 by using a suitable chemical vapor deposition (CVD) process, such that the lattice-like trench 116 is stuffed with the material forming the polycrystalline silicon layer 120.

After the formation of the polycrystalline silicon layer 120 is completed, as shown in FIG. 11D, respective redundant materials are removed from the polycrystalline silicon layer 120 and the silicon dioxide layer 118 by using either a suitable etching-back process or a suitable chemical mechanical polishing (CMP) process, so that a gate insulating layer 122 and a gate electrode layer 124 are defined in the N⁻-type drift layer 114. Of course, the gate electrode layer 124 features a lattice-like configuration, and a plurality of transistor-formation areas, in each of which a MOS transistor cell is to be produced, are defined in the N⁻-type drift layer 114, due to the lattice-like configuration of the gate electrode layer 124.

Thereafter, as shown in FIG. 11E, a silicon dioxide layer 126 is formed on both the N⁻-type drift layer 114 and the gate electrode layer 124 by using a thermal oxidization process. Namely, both a top surface of the N⁻-type drift layer 114 and a top surface of the gate electrode layer 124 are reformed by the thermal oxidization process so as to be covered with the silicon dioxide layer 126.

After the formation of the silicon dioxide layer 126 is completed, as shown in FIG. 11F, P-type impurities, such as boron ions (B⁺) or the like, are implanted in the N⁻-type drift layer 114, so that a plurality of P-type impurity-implanted regions 128L are defined in the respective transistor-formation areas. Note that each of the P-type impurity-implanted regions 128L features a relatively low impurity density.

After the definition of the P-type low density impurity-implanted regions 128L is completed, a photoresist layer 130 is formed on the silicon dioxide layer 126, and is patterned by using a photolithography process and a wet or dry etching process, so that a part of the P-type low density impurity-implanted regions 128L is masked with the patterned photoresist layer 130, as shown in FIG. 11G. Note, in this drawing, only one of the P-type low density impurity-implanted regions 128L is representatively masked with the patterned photoresist layer 130. Then, P-type impurities, such as boron ions (B⁺) or the like, are further implanted in the N⁻-type drift layer 114, so that each of the P-type low density impurity-implanted regions 128L except for the masked P-type low density impurity-implanted regions 128L is reformed as a P-type high density impurity-implanted region 128H.

Thereafter, the patterned photoresist layer 130 is removed from the silicon dioxide layer 126. Then, the P-type low and high density impurity-implanted regions 128L and 128H are subjected to an annealing process, so that each of the P-type low density impurity-implanted regions 128L is reformed as a P⁻-type low density impurity-diffusion region 132L, and so that each of the P-type high density impurity-implanted regions 128H is reformed as a P-type high density impurity-diffusion region 132H, as shown in FIG. 11H. Note, each of the impurity-diffusion regions 132L and 132H features a depth which is shallower than that of the lattice-like gate electrode layer 124.

After the formation of the P-type high density impurity-diffusion regions 132H and the P⁻-type low density impurity-diffusion regions 132L is completed, a photoresist layer 133 is formed on the silicon dioxide layer 126, and is patterned by using a photolithography process and a wet or dry etching process, so that respective central areas of the impurity-diffusion regions 132H and 132L are masked with the patterned photoresist layer 133, as shown in FIG. 11I. Then, N-type impurities, such as arsenic ions (As⁺) or the like, are implanted in each of the P-type high and low density impurity-diffusion regions 132H and 132L, so that a plurality of annular N⁺-type source regions 134 are formed in the respective impurity-diffusion regions 132H and 132L. Note, each of the annular N⁺-type source regions 134 features a depth which is shallower than that of a corresponding impurity-diffusion region (132H, 132L).

After the formation of the annular N⁺-type source regions 134 is completed, both the patterned photoresist layer 133 and the silicon dioxide layer 126 are removed from the surface of the processed N⁻-type drift layer 114. Then, a silicon dioxide layer 136 is formed as an insulating interlayer on the surface of the processed N⁻-type drift layer 114 by using a suitable CVD process, and is perforated by using a photolithography process and a wet or dry etching process, so that a contact hole 137 is formed therein at each of the density impurity-diffusion regions 132H and 132L, as shown in FIG. 11J. Namely, as is apparent from this drawing, the formation of the contact holes 137 is carried out such that an inner annular area of each of the annular N⁺-type source regions 134, surrounding a central area of a corresponding impurity-diffusion region (132H, 132L), is exposed to the outside, as shown in FIG. 11J.

After the formation of the perforated insulating interlayer 136 is completed, a conductive layer 138, composed of a suitable metal material, such as aluminum or the like, is formed as a source electrode layer on the insulating interlayer 136 by using a sputtering process, such that the contact holes 137 are stuffed with the metal material (aluminum), to thereby establish electrical connections between the annular N⁺-source regions 134, as shown in FIG. 11K. Then, a drain electrode layer 140 is formed on the rear surface of the N⁺-type semiconductor substrate 112, resulting in completion of production of the vertical-type power MOS devices in the semiconductor substrate 112 according to the present invention.

Thereafter, the semiconductor substrate 112 is subjected to a dicing process, in which it is cut along the scribe lines, whereby the vertical-type power MOS devices are separated from each other as bare chips.

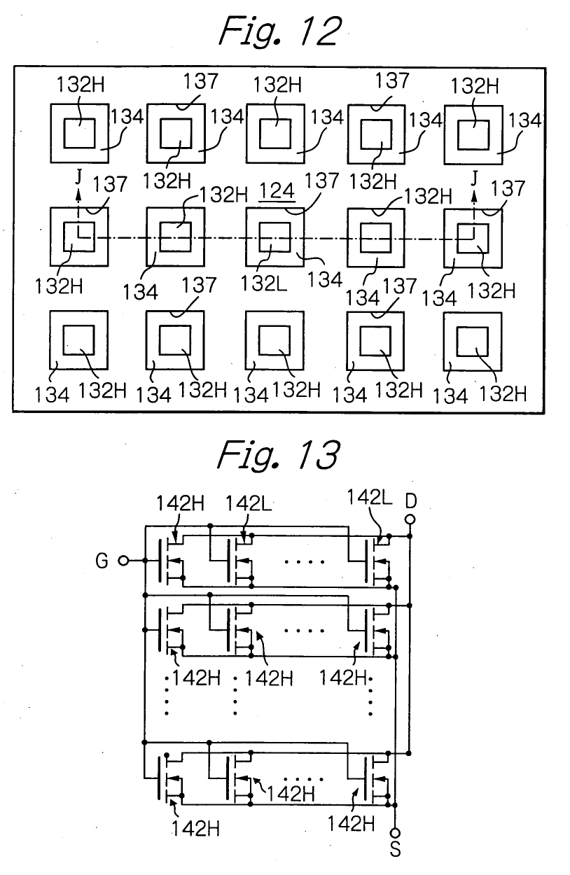

With reference to FIG. 12, one of the separated vertical-type power devices is representatively and conceptually shown in a plan view, from which the source electrode layer 138 is omitted to illustrate the insulating interlayer 136. Note, a cross-sectional view taken along the J-J of FIG. 12 corresponds to the cross-sectional view of FIG. 11J.

As is apparent from FIG. 12, the vertical-type power MOS device includes a plurality of MOS transistors arranged in the matrix manner on the N⁺-type semiconductor substrate 112, and each of the MOS transistors is referred to as a transistor cell. Note, although the vertical-type power MOS device includes only the twelve transistor cells, in reality, there are more than several thousand of the transistor cells therein.

As shown in FIG. 13 which shows a wiring diagram of the aforesaid vertical-type power MOS, the plurality of transistor cells, indicated by references 142H and 142L, are connected to each other in parallel so as to serve as a single MOS device having a drain D, a gate G and a source S. Of course, each of the transistor cells 142L having the P⁻-type low density impurity-diffusion region 132L features a low gate-threshold voltage, whereas each of the transistor cells 142H having the P-type high density impurity-diffusion region 132H features a high gate-threshold voltage. Namely, the gate-threshold voltage of the transistor cells 142H is higher than that of the transistor cells 142L.

In short, in this first embodiment, the vertical-type MOS device includes a first group of transistor cells 142H featuring high gate-threshold voltages which are substantially equal to each other, and a second group of transistor cells 142L featuring low gate-threshold voltages which are substantially equal to each other. A percentage of the transistor cells 142L may fall within a range between 5% and 20% with respect to a total of the transistor cells included in the vertical-type power MOS device.

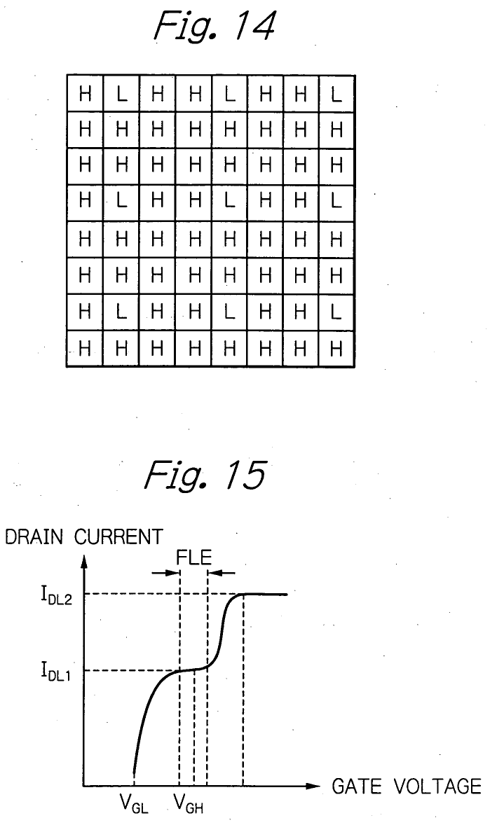

Preferably, as conceptually shown in FIG. 14 by way of example, the transistor cells 142L included in the first group are uniformly and regularly distributed in the arrangement of the transistor cells 142L and 142H. Note, in FIG. 14, each of the transistor cells 142L and 142H is represented by a square. Also, note, each of the squares, indicated by references “L”, is a transistor cell 142L featuring the low gate-threshold voltage, and each of the squares, indicated by references “H”, is a transistor cell 142H featuring the high gate-threshold voltage.

With reference to a graph shown in FIG. 15, a gate-voltage/drain-current characteristic of the first embodiment of the vertical-type power MOS device according to the present invention is represented by a solid curve. Note, in this graph, the abscissa representing a gate voltage applied to the gate G (FIG. 13) of the power MOS device is defined as a linear scale, whereas the ordinate representing a drain current flowing through the drain D (FIG. 13) is defined as a logarithmic scale. Also note, the low gate-threshold voltage of the transistor cells 142L is indicated by reference V_{GL}, and the high gate-threshold voltage of the transistor cells 142H is indicated by reference V_{GH}.

As shown in the graph of FIG. 15, when the gate voltage reaches the low gate-threshold voltage V_{GL}, the transistor cells 142L of the power MOS device are turned ON, so that the drain current starts to flow through the transistor cells 142L of the power MOS device. As the gate voltage is gradually raised from the low gate-threshold voltage V_{GL}, the drain current is abruptly and steeply increased. As the gate voltage becomes close to the high gate-threshold voltage V_{GH}, the increase of the drain current becomes small, and thus the change of the drain current is flattened. Namely, the drain current is saturated at a first stable level I_{DL1}, as shown in the graph of FIG. 15. Note, the saturated drain current I_{DL1} is a sum of currents flowing through only the transistor cells 142L of the power MOS device, and is determined by the number of the transistor cells 142L.

When the gate voltage reaches the high gate-threshold voltage V_{GH}, the transistor cells 142H of the power MOS device are turned ON so that the drain current is again abruptly and steeply increased. As the gate voltage becomes close to a given gate voltage V_{GX}, the increase of the drain current becomes small, and thus the change of the drain current is again flattened. Namely, the drain current is saturated at a second stable level I_{DL2}. Note, the saturated drain current I_{DL2} is a sum of currents flowing through all the transistor cells 142L and 142H of the power MOS device, and is determined by the number of the transistor cells 142H.

In short, as apparent from the graph of FIG. 15, the gate-voltage/drain-current characteristic of the first embodiment of the vertical-type power MOS device according to the present invention features a flat level extent FLE, in which the drain current I_{DL1} is not substantially varied by the change of the gate voltage.

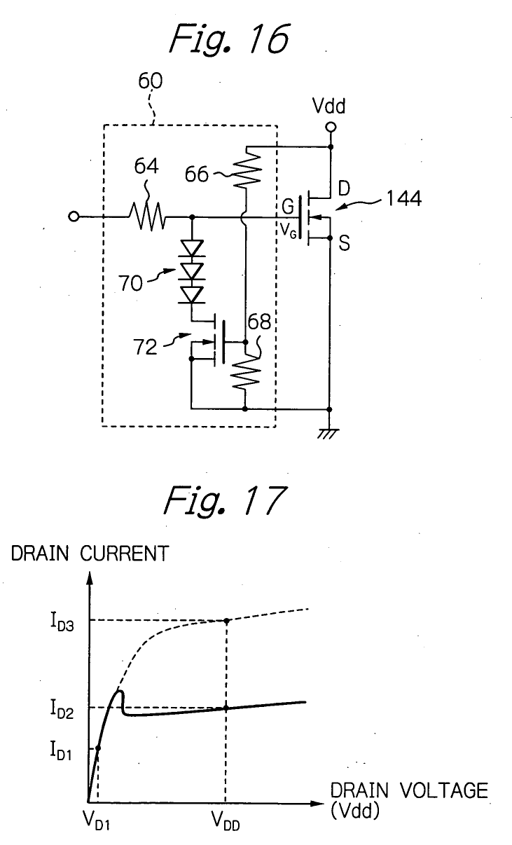

As shown in FIG. 16, for example, the second embodiment of the vertical-type power MOS device according to the present invention, generally indicated by reference 144, may be associated with a drive/protective circuit which is substantially identical to the drive/protective circuit 60 shown in FIG. 7. Note, in FIG. 14, the same references as in FIG. 7 represent the same elements.

Similar to FIG. 7, a drain D of the power MOS device 144 is connected to a main power source (not shown) through the intermediary of an electrical load circuit (not shown) and a source S of the power MOS device 144 is grounded. The power MOS device 144 serves as a switch device for controlling driving of the electrical load circuit, and a drain voltage V_{dd} is applied to the drain D of the power MOS device 144 from the main power source through the intermediary of the electrical load circuit. Also, in the drive/protective circuit 60, one terminal of the resistor 64 is connected to a gate G of the power MOS device 144, and the other terminal of the resistor 64 is connected to a power source (not shown). Two resistors 66 and 68, a set of diodes 70, and a MOS transistor 72 are arranged as shown in FIG. 14. Note, the set of diodes 70 have an internal resistance corresponding to the low gate-threshold voltage V_{GL}.

As stated above, it is substantially impossible to properly protect the second prior art vertical-type power MOS device (FIGS. 3 and 4) by the drive/protective circuit 60. However, the vertical-type power MOS device 144 according to the present invention can be properly protected by the drive/protective circuit 60, due to the gate-voltage/drain-current characteristic featuring the flat level extent FLE (I_{DL1}).

In particular, when the plurality of vertical-type power MOS devices 144 is manufactured as the production method as shown in FIGS. 11A to 11K, the elements forming each of the power MOS devices 144 are subjected to process fluctuations. Similarly, during the manufacture of the plurality of drive/protective circuits 60, the elements forming each of the drive/protective circuits 60 are subjected to process fluctuations, and thus a gate voltage to be applied to the gate G of the individual power MOS device 144 also fluctuates. Nevertheless, since the fluctuations of the gate voltage fall within the flat level extent FLE (I_{DL1}), the drain current flowing through the power MOS device 144 cannot be substantially influenced by the fluctuations of the gate voltage. Thus, the power MOS device 144 can be properly protected by the drive/protective circuit 60.

FIG. 17 shows a drain-voltage/drain-current characteristic of the vertical-type power MOS device 144 associated with the drive/protective circuit 60 shown in FIG. 16.

While the electrical load circuit (not shown) is normally driven by the drive/protective circuit 60, a predetermined gate voltage V_{G} (FIG. 16) is applied to the gate G of the power MOS device 144 through the intermediary of the resistor 64 so that a normal drain voltage V_{D1} is applied as the drain voltage V_{dd} to the drain D of the power MOS device 144, to thereby produce a normal drain current I_{D1} flowing through the power MOS device 144, as shown in the graph of FIG. 17. Note, an amount of the drain current I_{D1} is determined by a resistance of the electrical load circuit.

For example, when a short-circuit occurs in the electrical load circuit so that a power source voltage V_{DD} of the main power source is directly applied as the drain voltage V_{dd} to the drain D of the power MOS device 144, an abnormal excess drain current flows through the power MOS device 144. At this time, the application of the power source voltage V_{DD} to the drain D of the power MOS device 144 is detected by the resistor 66, and thus the MOS transistor 72 is turned ON. Thus, the gate voltage V_{G} (FIG. 16) is decreased to the low gate-threshold voltage V_{GL} (FIG. 15) which is determined by the set of diodes 70, so that the transistor cells 142H of the power MOS device 144 are turned OFF, whereby the increase of the drain current flowing the power MOS device 144 can be restrained at a small drain current I_{D2}, as shown in the graph of FIG. 17.

According to the present invention, even if the gate voltage is fluctuated, it is possible to securely ensure the constraint of the abnormal increase of the drain current, due to the gate-voltage/drain-current characteristic featuring the flat level extent FLE (I_{DL1}). On the other hand, in the case shown in FIG. 7, the drain current may follow a broken curve shown in the graph of FIG. 17, and may be considerably increased to an abnormally large current I_{D2}, due to the steep gate-voltage/drain-current characteristic SL shown in the graph of FIG. 5.

Note, it should be understood that the first embodiment of the vertical-type power MOS device according to the present invention may be associated with each of the drive/protective circuits 52, 74, 88 and 100 shown in FIGS. 6, 8, 9 and 10, and that it can be properly protected by the drive/protective circuit concerned (52, 74, 88, 100), due to the gate-voltage/drain-current characteristic featuring the flat level extent FLE (I_{DL1}).

### Second Embodiment

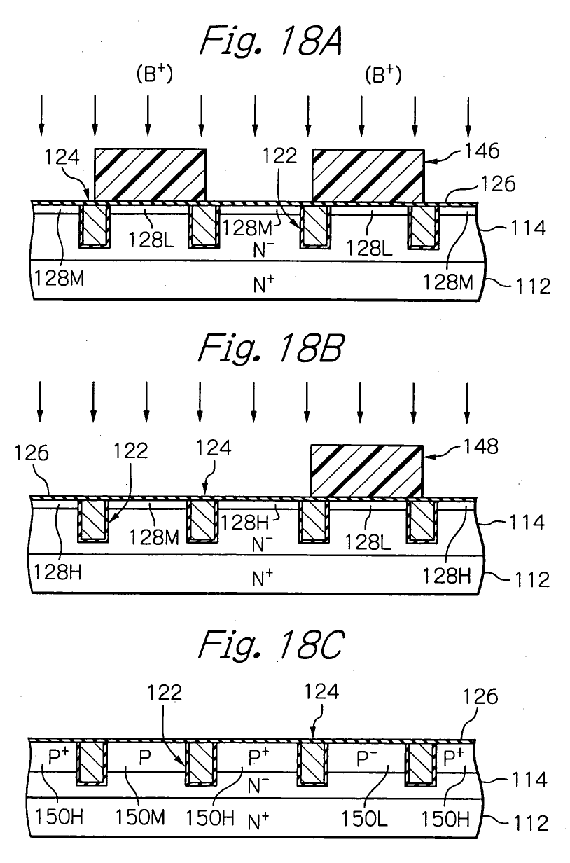

With reference to FIGS. 18A to 18D, a production method for manufacturing a second embodiment of the vertical-type power MOS device according to the present invention is explained below.

This production method includes first, second, third, fourth, fifth, and sixth representative steps, which are substantially identical to those of the first-mentioned production method as shown in FIGS. 11A to 11F. Note, in FIG. 18A, the same references as in FIG. 11F represent the same elements.

After the definition of the P-type low density impurity-implanted regions 128L is completed (FIG. 11F), a photoresist layer 146 is formed on the silicon dioxide layer 126, and is patterned by using a photolithography process and a wet or dry etching process, so that a part of the P-type low density impurity-implanted regions 128L is masked with the patterned photoresist layer 146, as shown in FIG. 18A. Note, in this drawing, only two of the P-type low density impurity-implanted regions 128L are representatively masked with the patterned photoresist layer 130. Then, P-type impurities, such as boron ions (B⁺) or the like, are again implanted in the N⁻-type drift layer 114, so that each of the P-type low density impurity-implanted regions 128L except for the masked P-type low density impurity-implanted regions 128L is reformed as a P-type medium density impurity-implanted region 128M, as shown in FIG. 18A.

After the formation of the P-type medium density impurity-implanted region 128M is completed, the patterned photoresist layer 146 is removed from the silicon dioxide layer 126, and a photoresist layer 148 is again formed on the silicon dioxide layer 126, and is patterned by using a photolithography process and a wet or dry etching process, so that a part of the remaining P-type low density impurity-implanted regions 128L is masked with the patterned photoresist layer 148, as shown in FIG. 18B. Note, in this drawing, only one of the P-type low density impurity-implanted regions 128L is representatively masked with the patterned photoresist layer 148. Then, P-type impurities, such as boron ions (B⁺) or the like, are further implanted in the N⁻-type drift layer 114, so that each of the P-type medium density impurity-implanted region 128M is reformed as a P-type high density impurity-implanted region 128H, and so that each of the P-type low density impurity-implanted regions 128L except for the masked P-type low density impurity-implanted regions 128L is reformed as a P-type medium density impurity-implanted region 128M, as shown in FIG. 18B.

Thereafter, the patterned photoresist layer 148 is removed from the silicon dioxide layer 126. Then, the P-type low, medium and high density impurity-implanted regions 128L, 128M and 128H are subjected to an annealing process, so that each of the P-type low density impurity-implanted regions 128L is reformed as a P⁻-type low density impurity-diffusion region 150L, so that each of the P-type medium density impurity-implanted regions 128M is reformed as a P-type medium density impurity-diffusion region 150M, and so that each of the P-type high density impurity-implanted regions 128H is reformed as a P⁺-type high density impurity-diffusion region 150H, as shown in FIG. 18C. Note, each of the impurity-diffusion regions 150L, 150M and 150H features a depth which is shallower than that of the lattice-like gate electrode layer 124.

Subsequently, both the semiconductor substrate 112 and the processed N⁻-type drift layer 114 are subjected to substantially the same processes as explained with reference to FIGS. 11I to 11K, resulting in completion of production of the vertical-type power MOS devices in the semiconductor substrate 112 according to the present invention, as shown in FIG. 18D. Note, in this drawing, reference 152 indicates an annular N⁺-type source region formed in each of the impurity-diffusion regions 150L, 150M and 150H; reference 154 indicates an insulating interlayer formed on the surface of the processed N⁻-type drift layer 114; reference 156 indicates a source electrode layer formed on the insulating interlayer 154; and reference 158 indicates a drain electrode layer formed on the rear surface of the N⁺-type semiconductor substrate 112.

Thereafter, the semiconductor substrate 112 is subjected to a dicing process, in which it is cut along the scribe lines, whereby the vertical-type power MOS devices are separated from each other as bare chips.

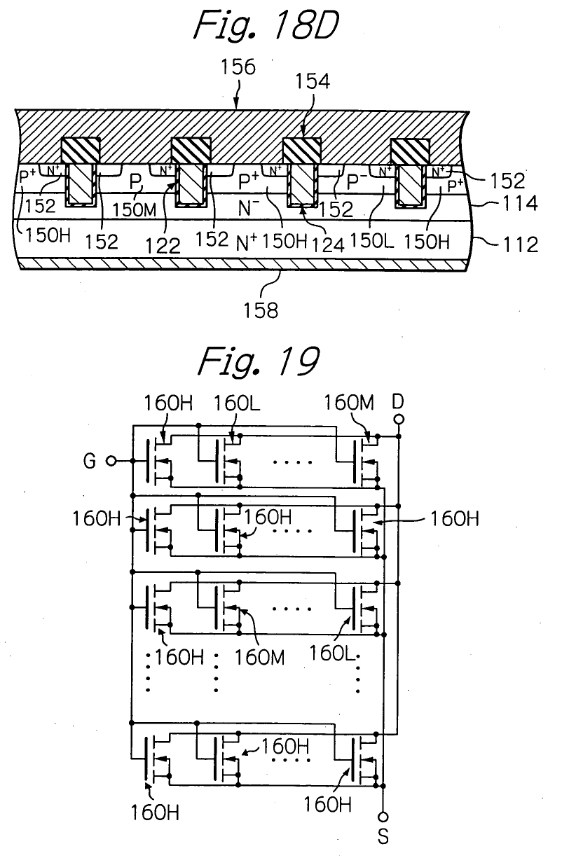

In this second embodiment, as shown in FIG. 19, the vertical-type power MOS device includes a plurality of MOS transistor cells 160L, 160M and 160M, which are arranged in the matrix manner on the N⁺-type semiconductor substrate 112, and which are connected to each other in parallel so as to serve as a single MOS device having a drain D, a gate G and a source S. Each of the transistor cells 160L has the P⁻-type low density impurity-diffusion region 150L, and features a low gate-threshold voltage. Also, each of the transistor cells 160M has the P-type medium density impurity-diffusion region 150M, and features a medium gate-threshold voltage. Similarly, each of the transistor cells 160H having the P⁺-type high density impurity-diffusion region 150H features a high gate-threshold voltage. Namely, the gate-threshold voltage of the transistor cells 160H is higher than that of the transistor cells 160M, and the gate-threshold voltage of the transistor cells 160M is higher than that of the transistor cells 160L.

In short, in this second embodiment, the vertical-type MOS device includes a first group of transistor cells 160H featuring high gate-threshold voltages which are substantially equal to each other, a second group of transistor cells 160M featuring medium gate-threshold voltages which are substantially equal to each other, and a third group of transistor cells 160L featuring low gate-threshold voltages which are substantially equal to each other. A percentage of the transistor cells 160L may fall within a range between 5% and 20% with respect to a total of the transistor cells included in the vertical-type power MOS device. Similarly, a percentage of the transistor cells 160M may fall within a range between 5% and 20% with respect to a total of the transistor cells included in the vertical-type power MOS device.

Similar to the above-mentioned first embodiment, preferably, the transistor cells 160L and 160M are uniformly and regularly distributed in the arrangement of the transistor cells 160L, 160M and 160H, as conceptually shown in FIG. 20 by way of example. Note, in FIG. 20, each of the transistor cells 160L, 160M and 160H is represented by a square. Also, note: each of the squares, indicated by references “L”, is a transistor cell 160L featuring the low gate-threshold voltage; each of the squares, indicated by references “M”, is a transistor cell 160M featuring the medium gate-threshold voltage; and each of the squares, indicated by references “H”, is a transistor cell 160H featuring the high gate-threshold voltage.

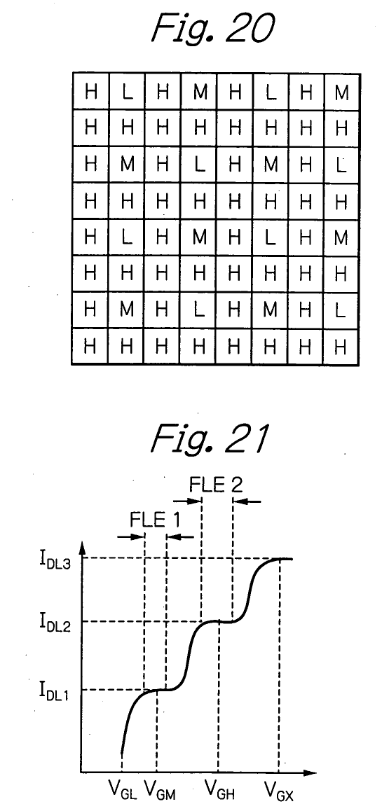

With reference to a graph shown in FIG. 21, a gate-voltage/drain-current characteristic of the second embodiment of the vertical-type power MOS device according to the present invention is represented by a solid curve. Note, in this graph, the abscissa representing a gate voltage applied to the gate G (FIG. 19) of the power MOS device is defined as a linear scale, whereas the ordinate representing a drain current flowing through the drain D (FIG. 19) is defined as a logarithmic scale. Also, note: the low gate-threshold voltage of the transistor cells 160L is indicated by reference V_{GL}; the medium gate-threshold voltage of the transistor cells 160L is indicated by reference V_{GM}, and the high gate-threshold voltage of the transistor cells 160H is indicated by reference V_{GH}.

As shown in the graph of FIG. 21, when the gate voltage reaches the low gate-threshold voltage V_{GL}, the transistor cells 160L of the power MOS device are turned ON, so that the drain current starts to flow through the transistor cells 160L of the power MOS device. As the gate voltage is gradually raised from the low gate-threshold voltage V_{GL}, the drain current is abruptly and steeply increased. As the gate voltage becomes close to the medium gate-threshold voltage V_{GM}, the increase of the drain current becomes small, and thus the change of the drain current is flattened. Namely, the drain current is saturated at a first stable level I_{DL1}, as shown in the graph of FIG. 21. Note, the saturated drain current I_{DL1} is a sum of currents flowing through only the transistor cells 160L of the power MOS device, and is determined by the number of the transistor cells 160L.

When the gate voltage reaches the medium gate-threshold voltage V_{GM}, the transistor cells 160M of the power MOS device are turned ON so that the drain current is again abruptly and steeply increased. As the gate voltage becomes close to the high gate-threshold voltage V_{GH}, the increase of the drain current becomes small, and thus the change of the drain current is again flattened. Namely, the drain current is saturated at a second stable level I_{DL2}. Note, the saturated drain current I_{DL2} is a sum of currents flowing through the transistor cells 160L and 160M of the power MOS device, and is determined by the number of the transistor cells 160L and 160M.

When the gate voltage reaches the high gate-threshold voltage V_{GH}, the transistor cells 160H of the power MOS device are turned ON so that the drain current is further abruptly and steeply increased. As the gate voltage becomes close to a given gate voltage V_{GX}, the increase of the drain current becomes small, and thus the change of the drain current is further flattened. Namely, the drain current is saturated at a third stable level I_{DL3}. Note, the saturated drain current I_{DL3} is a sum of currents flowing all the transistor cells 160L, 160M and 160H of the power MOS device, and is determined by the number of the transistor cells 160L, 160M and 160H.

In short, as apparent from the graph of FIG. 21, the gate-voltage/drain-current characteristic of the second embodiment of the vertical-type power MOS device according to the present invention features a first flat level extent FLE1, in which the drain current I_{DL1} is not substantially varied by the change of the gate voltage, and a second flat level extent FLE2, in which the drain current I_{DL2} is not substantially varied by the change of the gate voltage.

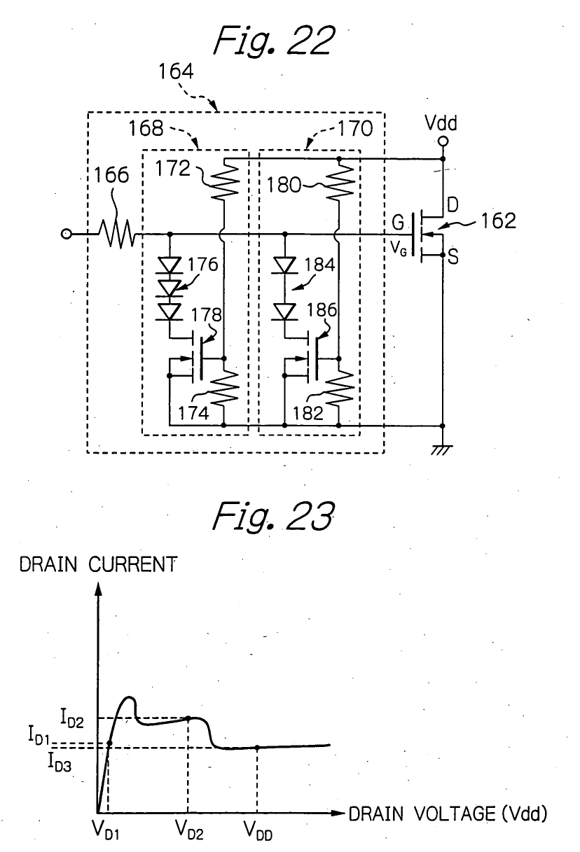

As shown in FIG. 22, the second embodiment of the vertical-type power MOS device according to the present invention, generally indicated by reference 162, may be associated with a drive/protective circuit 164.

A drain D of the power MOS device 162 is connected to a main power source (not shown) through the intermediary of an electrical load circuit (not shown), and a source S of the power MOS device 162 is grounded. The power MOS device 162 serves as a switch device for controlling driving of the electrical load circuit, and a drain voltage V_{dd} is applied to the drain D of the power MOS device 162 from the main power source through the intermediary of the electrical load circuit.

The drive/protective circuit 164 includes a resistor 166, one terminal of which is connected to a gate G of the power MOS device 162, and the other terminal of the resistor 166 is connected to a power source (not shown). Also, the drive/protective circuit 164 is provided with a first protective circuit 168 and 170. The first protective circuit 168 includes two resistors 172 and 174, a set of diodes 176, and a MOS transistor 178, which are arranged as shown in FIG. 22. The second protective circuit 170 includes two resistors 180 and 182, a set of diodes 184, and a MOS transistor 186, which are arranged as shown in FIG. 22.

As is apparent from FIG. 22, the set of diodes 176 and the set of diodes 184 are connected to each other in parallel, and both the two sets of diodes 176 and 182 have an internal resistance corresponding to the low gate-threshold voltage V_{GL}. The set of diodes 176 itself has an internal resistance corresponding to the medium gate-threshold voltage V_{GM}. The MOS transistor 174 features a gate-threshold voltage which is smaller than that of the MOS transistor 186.

Similar to the above-mentioned first embodiment, when the plurality of vertical-type power MOS devices 162 is manufactured as the second-mentioned production method as shown in FIGS. 18A to 18D, the elements forming each of the power MOS devices 162 are subjected to process fluctuations. Also, during the manufacture of the plurality of drive/protective circuits 164, the elements forming each of the drive/protective circuits 164 are subjected to process fluctuations, and thus a gate voltage to be applied to the gate G of the individual power MOS device 162 also fluctuates. Nevertheless, it is possible to properly protect the power MOS device 162 by the drive/protective circuit 164 for substantially the same reasons as in the above-mentioned first embodiment.

FIG. 23 shows a drain-voltage/drain-current characteristic of the vertical-type power MOS device 162 associated with the drive/protective circuit 164 shown in FIG. 22.

While the electrical load circuit (not shown) is normally driven by the drive/protective circuit 162, a predetermined gate voltage V_{G} (FIG. 22) is applied to the gate G of the power MOS device 144 through the intermediary of the resistor 166 so that a normal drain voltage V_{D1} is applied as the drain voltage V_{dd} to the drain D of the power MOS device 162, to thereby produce a normal drain current I_{D1} flowing through the power MOS device 144, as shown in the graph of FIG. 23. Note, an amount of the drain current I_{D1} is determined by a resistance of the electrical load circuit.

For example, when a malfunction occurs in the electrical load circuit so that an abnormal drain voltage V_{D2} (FIG. 23) higher than the normal drain voltage V_{D1} is applied as the drain voltage V_{dd} to the drain D of the power MOS device 162, an excess drain current flows through the power MOS device 144. At this time, the application of the abnormal drain voltage V_{D2} to the drain D of the power MOS device 162 is detected by the resistor 172, and thus the MOS transistor 174, featuring the gate-threshold voltage smaller than that of the MOS transistor 186, is turned ON. Thus, the gate voltage V_{G} (FIG. 22) is decreased to the medium gate-threshold voltage V_{GM} (FIG. 21), which is determined by the set of diodes 176, so that the transistor cells 160H of the power MOS device 162 are turned OFF, whereby the increase of the drain current flowing the power MOS device 162 can be restrained at a small drain current I_{D2}, as shown in the graph of FIG. 23.

When a short-circuit occurs in the electrical load circuit without the malfunction being repaired, so that a power source voltage V_{DD} of the main power source is directly applied as the drain voltage V_{dd} to the drain D of the power MOS device 162, an abnormal excess drain current flows through the power MOS device 162. At this time, the application of the power source voltage V_{DD} to the drain D of the power MOS device 162 is detected by the resistor 180, and thus the MOS transistor 186 is turned ON. Thus, the gate voltage V_{GM}, applied to the gate G of the power MOS device 162, is further decreased to the low gate-threshold voltage V_{GL} (FIG. 21), which is determined by both the sets of diodes 176 and 184 connected to each other in parallel, so that the transistor cells 160M and 160H of the power MOS device 162 are turned OFF, whereby the increase of the drain current flowing the power MOS device 182 can be restrained at a smaller drain current I_{D3} than the drain current I_{D2}, as shown in the graph of FIG. 23.

Similar to the above-mentioned first embodiment, in this second embodiment, even if the gate voltage is fluctuated, it is possible to securely ensure the constraint of the abnormal increase of the drain current flowing through the power MOS device 162, due to the gate-voltage/drain-current characteristic featuring the first and second flat level extents FLE1 and FLE2 (I_{DF1} and I_{DF2}).

In the above-mentioned embodiments, although impurity densities are regulated to thereby obtain the different gate-threshold voltages in the transistor cells (142H, 142L; 160H, 160M, 160L), another factor, such as a thickness of the gate electrode layer 124 and so on, may be regulated for obtaining the different gate-threshold voltages.

JP-A-H11-214527 discloses a MOS device includes a plurality of MOS elements connected to each other in parallel, and the MOS elements feature respective gate-threshold voltages which are different from each other, to thereby obtain a stable cutoff frequency characteristic (ft) and a stable mutual conductance characteristic (gm) regardless of variation of an input gate voltage. On the contrary, for example, in the first embodiment of the vertical-type power MOS device according to the present invention, a part (142L) of the transistor cells (142H, 142L) features the gate-threshold voltage which is lower than the remaining part (142H) of the transistor cells to thereby protect the power MOS device from an excess drain current. In this connection, the vertical-type power MOS device according to the present invention is different from the MOS device disclosed in JP-A-H11-214527.

Finally, it will be understood by those skilled in the art that the foregoing description is of preferred embodiments of the method and the device, and that various changes and modifications may be made to the present invention without departing from the spirit and scope thereof.

1. A vertical-type power metal oxide semiconductor device comprising:
a semiconductor substrate; and
a plurality of transistor cells formed and arranged on said semiconductor substrate so as to be electrically connected to each other in parallel,
wherein said transistor cells are sorted into at least two groups, a first group of transistor cells featuring a gate-threshold voltage which is higher than that of a second group of transistor cells.

2. The vertical-type power metal oxide semiconductor device as set forth in claim 1, wherein the transistor cells included in said second group are substantially uniformly distributed in the arrangement of all said transistor cells.

3. The vertical-type power metal oxide semiconductor device as set forth in claim 1, wherein a percentage of the transistor cells included in said second group falls within a range between 5% and 20% with respect to a total of the transistor cells.

4. The vertical-type power metal oxide semiconductor device as set forth in claim 1, wherein all said transistor cells are arranged in a matrix manner.

5. A vertical-type power metal oxide semiconductor device comprising:
a semiconductor substrate; and
a plurality of transistor cells formed and arranged on said semiconductor substrate so as to be electrically connected to each other in parallel,
wherein said transistor cells are sorted into at least three groups, a first group of transistor cells featuring a gate-threshold voltage which is higher than that of a second group of transistor cells, the second group of transistor cells featuring a gate-threshold voltage which is higher than that of a third group of transistor cells.

6. The vertical-type power metal oxide semiconductor device as set forth in claim 5, wherein the transistor cells included in said second group and the transistor cells included in said third group are substantially uniformly distributed in the arrangement of all said transistor cells.

7. The vertical-type power metal oxide semiconductor device as set forth in claim 5, wherein each of percentages of the transistor cells included in said second group and the transistor cells included in said third group falls within a range between 5% and 20% with respect to a total of the transistor cells.

8. The vertical-type power metal oxide semiconductor device as set forth in claim 5, wherein all said transistor cells are arranged in a matrix manner.

9. A combination of a vertical-type power metal oxide semiconductor device and a drive/protective circuit,
wherein said vertical-type power metal oxide semiconductor device comprises a semiconductor substrate, and a plurality of transistor cells formed and arranged on said semiconductor substrate so as to be electrically connected to each other in parallel, said transistor cells being sorted into at least two groups, a first group of transistor cells featuring a gate-threshold voltage which is lower than that of a second group of transistor cells, and
wherein said drive/protective circuit is constituted such that a drive voltage is applied to a gate of said vertical-type power metal oxide semiconductor device to thereby turn ON all said transistor cells, and such that a given excess drain current flowing through said vertical-type power metal oxide semiconductor device is detected to thereby turn OFF said transistor cells included in said first group.

10. The combination as set forth in claim 9, wherein the transistor cells included in said second group are substantially uniformly distributed in the arrangement of all said transistor cells.

11. The combination as set forth in claim 9, wherein a percentage of the transistor cells included in said second group falls within a range between 5% and 20% with respect to a total of the transistor cells.

12. The combination as set forth in claim 9, wherein all said transistor cells are arranged in a matrix manner.

13. A combination of a vertical-type power metal oxide semiconductor device and a drive/protective circuit,
wherein said vertical-type power metal oxide semiconductor device comprises a semiconductor substrate, and a plurality of transistor cells formed and arranged on said semiconductor substrate so as to be electrically connected to each other in parallel, said transistor cells being sorted into at least three groups, a first group of transistor cells featuring a gate-threshold voltage which is higher than that of a second group of transistor cells, the second group of transistor cells featuring a gate-threshold voltage which is higher than that of a third group of transistor cells, and
wherein said drive/protective circuit is constituted such that a drive voltage is applied to a gate of said vertical-type power metal oxide semiconductor device to thereby turn ON all said transistor cells, such that a first given excess drain current flowing through said vertical-type power metal oxide semiconductor device is detected to thereby turn OFF said transistor cells included in said first group, and such that a second given excess drain current, which is larger than said first excess drain current, is detected to thereby turn OFF said transistor cells included in said second group.

14. The combination as set forth in claim 13, wherein the transistor cells included in said second group and the transistor cells included in said third group are substantially uniformly distributed in the arrangement of all said transistor cells.

15. The combination as set forth in claim 13, wherein each of percentages of the transistor cells included in said second group and the transistor cells included in said third group falls within a range between 5% and 20% with respect to a total of the transistor cells.

16. The combination as set forth in claim 13, wherein all said transistor cells are arranged in a matrix manner.
